(19) United States
(12) Patent Application Publication
(10) Pub. No.: US 2020/0271698 A1
(43) Pub. Date: Aug. 27, 2020

(54) Galvanic Isolated Ceramic Based Voltage Sensors

(71) Applicant: QORTEK, INC., Williamsport, PA (US)

(72) Inventors: Gareth J. KNOWLES, Williamsport, PA (US); Ross BIRD, Williamsport, PA (US); William M. BRADLEY, Williamsport, PA (US)

(73) Assignee: QorTek, Inc., Williamsport, PA (US)

(21) Appl. No.: 16/063,072

(22) PCT Filed: Apr. 1, 2015
(86) PCT No.: PCT/US2015/023930

§ 371 Date: Jun. 15, 2018

Related U.S. Application Data
(60) Provisional application No. 61/973,583, filed on Apr. 1, 2014.

(51) Int. Cl. G01R 15/26; G01R 15/06; H01L 41/107

(52) U.S. Cl. CPC G01R 15/26; H01L 41/107; G01R 15/06

(57) ABSTRACT

A galvanically isolated voltage sensor is provided which includes a mechanically integral piezoelectric transformer assembly coupled to a modulation circuit. The modulation circuit receives a source voltage signal to be measured and modulates that signal at a frequency equal to a resonance frequency of the transformer assembly and transmits the modulated to signal to the transformer assembly. The transformer assembly generates an output signal that is identical to the modulated signal subject to the transformer gain. The output signal is then demodulated and filtered so as to recreate the source voltage signal for analysis.

This application claims the benefit of U.S. provisional Application Ser. No. 61/973,583 filed Apr. 1, 2014 which is hereby incorporated by reference.

### I. TECHNICAL FIELD

The invention relates to a galvanically isolated device capable of monitoring, tracking, or transmitting voltage waveforms of either analog type or low frequency digital type.

### II. BACKGROUND ART

Applications requiring galvanic isolation include industrial sensors, medical transducers, auxiliary converters, battery chargers, choppers, and mains powered switchmode power supplies. Operator safety and signal quality are insured with isolated interconnections. Such isolated interconnection often incorporates isolation amplifiers as to provide the capability of monitoring the voltage level.

For some instruments and sensors, low-level DC and AC voltage levels must be accurately monitored even in the presence of high common-mode noise. Voltage sensors facilitate monitoring of voltage levels within an electrical system. They identify undervoltage or overvoltage concerns and their isolation capability can be used to protect other parts of the electronics that are connected to the voltage level being monitored. Such devices are commonly used to detect occurrence of any variation from nominal voltage, provide voltage tracking and data logging of performance, provide electrical isolation between two electrically connected subcircuits or components within an electrical system, identify phase-loss conditions, monitor overvoltage/undervoltage conditions as to aid in diagnosis, indicate voltage conditions that may cause stress in or damage to soft start components (SSCs). Such devices that measure AC voltage levels are used in applications such as power demand control, power failure detection, load sensing, safety switching, and motor overload control. Electrical voltage sensors that measure DC voltages are used in energy management control systems (EMCS), rail monitoring systems, building control systems (BCS), fault detection, data acquisition, and temperature control. They are also used in power measurement, analysis, and control.

It is straightforward to design non-isolated voltage amplifiers/sensors. Prior art teaches simple methods of obtaining non-isolated voltage level shifting from either AC or DC voltage to DC voltage using either voltage divider networks or capacitor divider networks (mainly for low current applications). For example, a resistor divider network can be directly coupled to the anode and cathode of the potential to be monitored. In this approach the output voltage of the appropriately selected second leg of the voltage divider is fed into an analog-to-digital converter, for example consisting of an op-amp in a voltage follower configuration that feeds into a low-pass filter. A more complex version of this is provided in Reference [1] for generalized ground loop configurations. An issue that such designs raise is that there can be serious equipment problems and/or human safety challenges when employing a non-isolated amplifier/sensor. Such concerns cause electronics designers to add an isolation stage as to ensure that equipment is electrically isolated. Providing electrical isolation eliminates ground loops, also common-mode range of data acquisition system can be increased, and it enables level shifting of the signal ground reference to a single system ground. It also enhances the ability of an electrical system to prevent high-voltage and transient voltages to be transmitted across its boundary to other, more sensitive, electronics or even a user. For example, by adding a transformer isolation coupling between the voltage signal and the resistive divider network by adding protection diodes to ground and power supply at the rail pins of the op-amp. Such isolation transformers are often designed to have insulation between primary and secondary as to withstand any occurrence of high voltage between windings.

To enable such isolated voltage monitoring/level shifting requires a more complex methodology. The existing methodology is to have a first stage that is a voltage-to-charge converter and a second stage that is a charge detector. In such isolated voltage transformers, a magnetic-coupled isolation stage such as that of Reference [2] or switched capacitor (SC) coupling circuit such as that of Reference [3] may be employed as to provide isolation voltage sensing.

There are two kinds of voltage sensors commonly used; these are either of the ‘in-line’ voltage sensors type or non-intrusive type. Both types of voltage sensor can be employed to measure current flow using a magnetic coupling effect. Usually such voltage sensors are based on using the Hall Effect. These sensors enable measurement of direct, alternating and impulse voltages with galvanic insulation between the primary and secondary circuits through current in a primary winding of a gapped magnetic transformer as caused by the voltage source of interest to be monitored. This, in turn, causes a magnetic flux in (the primary winding of) the magnet circuit. The gapped magnetic transformer channels this magnetic flux. A Hall Effect probe placed within this air gap provides a voltage proportional to this flux, and therefore proportional to the voltage source of interest.

Prior art such as disclosed in Reference [4] and Reference [5] describe a second method of providing an isolated voltage sensor that is obtained by employing a switched-capacitor (SC) coupling circuit. Prior art utilizes an input differential signal which is converted to a proportional charge on the capacitor by gates controlling charging and discharging of appropriate capacitors. Then the charge is detected by a differential amplifier with high input resistance. The isolation barrier is established by a configuration of capacitors and an array of gating switches. Reference [6] describes a simplified version of such a circuit.

Opto-isolators have been commonly used to isolate voltage; however, such optical devices have well-established issues with temperature causing them to degrade. There is a further issue that the measurement signals they produce can be nonlinear. A linearizing feedback can be added on the isolated side to obtain desired linear performance, but this requires an isolated power supply to operate an op amp on the output side. Opto-isolators have further problems for missile and space applications in that these devices are subject to photonic caused measurement corruption.

Another approach has been published that exploits piezoelectric effects. Piezo-optical voltage isolators have been demonstrated by hard attaching a piezoelectric device to a fiber-optic cable. In Reference [7] ABB Corporation introduced an approach for a sensing high-voltage flow wherein a Bragg grated optical fiber is mechanically fixed along the radial direction of a conventional piezoelectric disc. A wavelength shift modulation is obtained as a result of the converse piezoelectric effect as a function of applied source voltage to a pair of electrodes. A demodulation scheme is introduced for the attached fiber Bragg sensor based on source spectral characteristics as to derive the voltage waveform amplitude. This prior art is an example of inferring voltage level by the change in a fiber-optic cable property as a function of the strain induced in a piezoelectric device hard coupled to the cable and subject to a high electrical field that is to be measured. See References [8], [9], [10]. Piezo-optical voltage isolators have many serious drawbacks as voltage sensors, they rely on assurance of intimate mating of the fiber and piezoelectric devices, they require that the piezoelectric device be isolated and they can only measure voltage for the situations of high electrical field. There can be inaccuracies due to noise coupling between the high-voltage (HV) source and the electric strain gauge, and these devices rely on having pre-generated a model of the strain coupling behavior. The biggest issues are that these fiber-optic coupled voltage sensors can only measure a low frequencies and only for high voltages, rendering them not-useful for the vast majority of applications.

Reference [11] introduces a piezoelectric transformer as an isolated voltage sensor that dispenses with the need for a fiber-optic cable. As with a magnetic transformer, a piezoelectric transformer has a primary electroded capacitor and a secondary electroded capacitor that are separated by a non-electroded region. The device processes the output side electrical signal of a transformer to gain knowledge of the voltage signal to be monitored or transmitted, where this voltage signal functions as the as the driving voltage on the primary side of said transformer. Because the primary and secondary capacitors are separated by a non-electroded region the input and output signals are galvanic isolation. In fact, such ceramic isolation can be designed to have larger isolation than a comparable magnetic transformer based voltage sensor.

Reference [11] identifies that designing such piezoelectric transformer to operate as a resonance device introduces some significant drawbacks. At low frequencies, the voltage signals will not be sufficient to excite a piezoelectric transformer designed to operate at resonance, causing the transformer to be physically large (as dictated by the long wavelength). Reference [11] also identifies the drawback that, due to it having a high mechanical quality factor, a resonant piezoelectric transformer is a narrow band transformer that can only sense or transmit voltage signals in the range of frequencies close to its resonant frequency. Because resonance piezotransformers possess high frequency, such voltage sensors will be simply unable to measure low frequency and near-dc voltage signals. Reference [11] further identifies the drawback that such a resonant piezoelectric voltage sensor will require accurate gain between the primary and secondary. For these reasons, even though there are significant drawbacks, the prior art of directly coupled piezotransformer based voltage sensors has centered on ‘off-resonance’ design.

One of the problems with non-resonant piezotransformer based voltage sensors is that they demonstrate only low energetic efficiency and low gain capability. They also require a housing that applies mechanical pre-stress. Such housings can be very complex as they require a means to adjust the pre-load condition to compensate for changes in electrical load at the output. Because the transformer behavior now becomes dependent on the stiffness with the pre-stress, the housing now needs to incorporate force measurement capability. The resulting voltage sensor is only capable of low energetic efficiency and low gain capabilities, further restricting its applicability.

### III. SUMMARY OF THE INVENTION

An object of at least one embodiment of the invention is to provide a piezotransformer circuit that can monitor or transmit analog or digital voltage signal information in an isolated fashion that does not require optical, magnetic transformer or switched capacitive coupling components.

Another object of at least one embodiment of the present invention is to provide an analog piezotransformer circuit that can monitor or transmit analog or digital voltage signal information in an isolated fashion that does not require optical, magnetic transformer or switched capacitive coupling components.

An additional object of at least one embodiment of the invention is that it provides a piezotransformer circuit that can monitor or transmit analog voltage signal information in an isolated fashion over a wide bandwidth that can be as low as near dc at lower end and can in the MHz range at the upper end without requiring any additional components or supplementary power supply.

A further object of at least one embodiment of the invention is that it provides a piezotransformer circuit that can monitor or transmit digital voltage signal information in an isolated fashion at less than 2 MHz bandwidth without requiring any additional components or supplementary power supply.

Yet another object of at least one embodiment of the invention is to provide an isolated piezotransformer circuit that can accurately monitor or transmit a very low power voltage signal in an isolated fashion.

Still a further object of at least one embodiment of the invention is to provide a piezotransformer circuit that can accurately monitor or transmit a voltage signal with very high galvanic isolation and negligible capacitive coupling.

Another object of at least one embodiment of the present invention is to provide isolated voltage waveform monitoring that is highly efficient without incorporating dedicated measurement, isolation or feedback circuitry.

Another object of at least one embodiment the present invention is to provide a piezotransformer circuit that can operate over a very wide thermal range between low ambient temperatures that can include up to high ambient temperatures.

A further object at least one embodiment of the present invention is at least one piezotransformer circuit embodiment of a voltage isolator, monitor or transmitter that can operate over a very wide thermal range that can include down to low ambient temperatures.

Another objective of the present invention is at least one piezotransformer circuit embodiment that provides an extremely radiation tolerant voltage isolator or isolated voltage sensor.

In at least one embodiment, a galvanically isolated voltage sensor has a mechanically integral piezoelectric transformer assembly that comprises at least first and second distinct galvanically isolated outputs and at least one input. The mechanically integral piezoelectric transformer assembly generates a modulation carrier signal having a frequency equal to a mechanical resonance frequency of the mechanically integral piezoelectric transformer assembly. A modulation circuit is provided which has a first input coupled to the first galvanically isolated output of the mechanically integral piezoelectric transformer assembly and receives the modulation carrier signal. The modulation circuit further receives a source voltage signal and modulates the source voltage signal with the modulation carrier signal to generate a modulation circuit output signal. The modulation circuit is connected to and transmits the modulation circuit output signal to at least one input of the mechanically integral piezoelectric transformer assembly, thereby forming an internal self-oscillating circuit within the piezoelectric transformer assembly. One or more demodulators are coupled to the one or more outputs of the mechanically integral piezoelectric transformer assembly, where the mechanically integral piezoelectric transformer assembly outputs a piezoelectric transformer assembly signal that is proportional to the modulated voltage source signal.

In one embodiment, a galvanically isolated voltage sensor has a mechanically integral piezoelectric transformer assembly that comprises at least first and second distinct galvanically isolated outputs and at least one input. A start circuit is operatively coupled with the mechanically integral piezoelectric transformer assembly to initiate transformer operation. The mechanically integral piezoelectric transformer assembly generates a modulation carrier signal having a frequency equal to a mechanical resonance frequency of the mechanically integral piezoelectric transformer assembly. A modulation circuit is provided which has a first input coupled to the first galvanically isolated output of the mechanically integral piezoelectric transformer assembly and receives the modulation carrier signal. The modulation circuit further receives a source voltage signal and modulates the source voltage signal with the modulation carrier signal to generate a modulation circuit output signal. The modulation circuit is connected to and transmits the modulation circuit output signal to at least one input of the mechanically integral piezoelectric transformer assembly, thereby forming an internal self-oscillating circuit within the piezoelectric transformer assembly. One or more demodulators are coupled to the one or more outputs of the mechanically integral piezoelectric transformer assembly, where the mechanically integral piezoelectric transformer assembly outputs a piezoelectric transformer assembly signal that is proportional to the modulated voltage source signal.

In still another embodiment of the invention, a voltage sensor includes a mechanically integral piezoelectric transformer assembly having at least first and second distinct galvanically isolated outputs and at least one input. The mechanically integral piezoelectric transformer assembly generates a modulation carrier signal that has a frequency equal to a mechanical resonance frequency of the mechanically integral piezoelectric transformer assembly. A linear boost circuit is provided that receives a source voltage signal and amplifies source voltage signal. A start circuit is operatively coupled to the mechanically integral piezoelectric transformer assembly to initiate transformer operation. A modulation circuit which has a first input coupled to the first galvanically isolated output of the mechanically integral piezoelectric transformer assembly and receives the modulation carrier signal. The modulation circuit receives the amplified source voltage signal from the linear boost circuit and modulates the amplified source voltage signal with the modulation carrier signal to generate a modulation circuit output signal. The modulation circuit is connected to and transmits the modulation circuit output signal to at least one input of the mechanically integral piezoelectric transformer assembly, thereby forming an internal self-oscillating circuit within the piezoelectric transformer assembly. One or more demodulators are coupled to the one or more outputs of the mechanically integral piezoelectric transformer assembly which outputs a piezoelectric transformer assembly signal that is proportional to the modulated voltage source signal.

### IV. BRIEF DESCRIPTION OF THE DRAWINGS

FIG. 1 shows an isolated voltage sensor in accordance with an embodiment of the invention.

FIG. 2A illustrates an isolated voltage sensor in accordance with an embodiment of the invention that employs a piezoelectric subtransformer.

FIG. 2B depicts an isolated voltage sensor in accordance with an embodiment of the invention that employs a piezoelectric subtransformer.

FIG. 3 shows a further embodiment of the isolated voltage sensor of the invention where the isolated voltage sensor includes a start circuit.

FIG. 4 illustrates a further embodiment of the isolated voltage sensor of the invention depicting components of the modulation circuit.

FIG. 5 depicts yet another embodiment of the isolated voltage sensor of the invention.

FIG. 6 illustrates a further embodiment of the isolated voltage sensor of the invention.

FIG. 7A shows still another embodiment of the isolated voltage sensor of the invention.

FIG. 7B illustrates an additional embodiment of the isolated voltage sensor of the invention.

FIG. 8 depicts another embodiment of the isolated voltage sensor of the invention.

FIG. 9 illustrates yet a further embodiment of the isolated voltage sensor of the invention.

FIG. 10 depicts another embodiment of the isolated voltage sensor of the invention.

FIG. 11 shows still another embodiment of the isolated voltage sensor of the invention.

FIG. 12 shows a further embodiment of the isolated voltage sensor of the invention.

FIG. 13 illustrates another embodiment of the isolated voltage sensor of the invention.

FIG. 14 depicts another embodiment of the isolated voltage sensor of the invention.

FIG. 15 illustrates an example of a start circuit used in several embodiments of the isolated voltage sensor of the invention.

FIG. 16 depicts an example of a demodulator used in several embodiments of the isolated voltage sensor of the invention.

FIG. 17 illustrates an example of a piezoelectric transformer assembly used in several embodiments of the isolated voltage sensor of the invention.

FIG. 18 another example of a piezoelectric transformer assembly used in several embodiments of the isolated voltage sensor of the invention.

FIG. 19 shows another example of a piezoelectric transformer assembly used in several embodiments of the isolated voltage sensor of the invention.

### V. DESCRIPTION OF THE EMBODIMENTS OF THE INVENTION

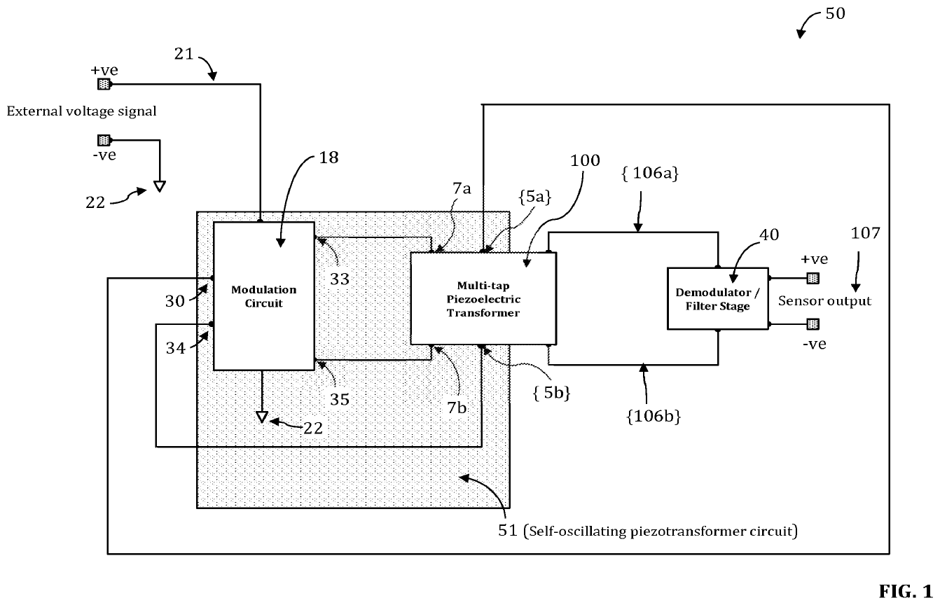

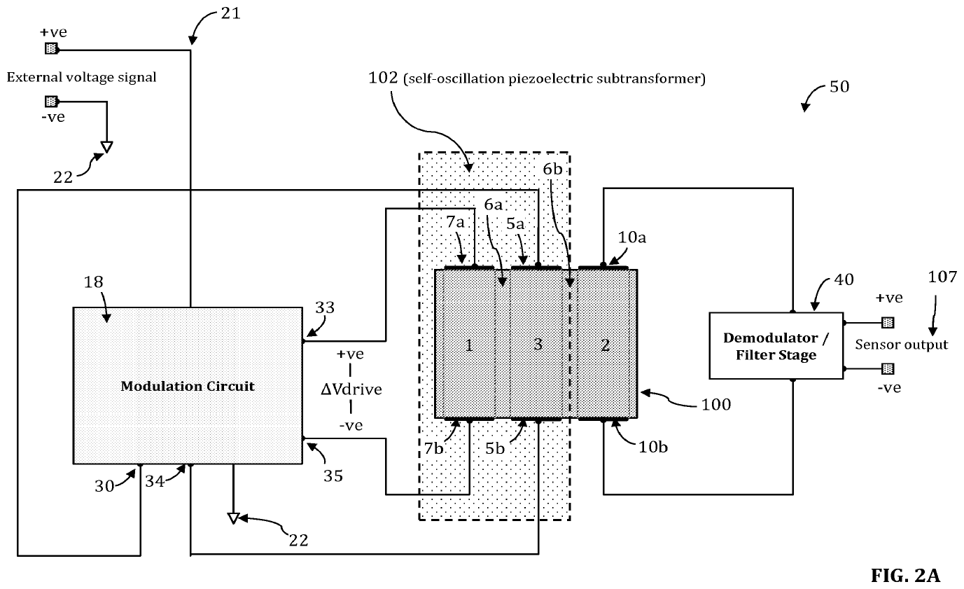

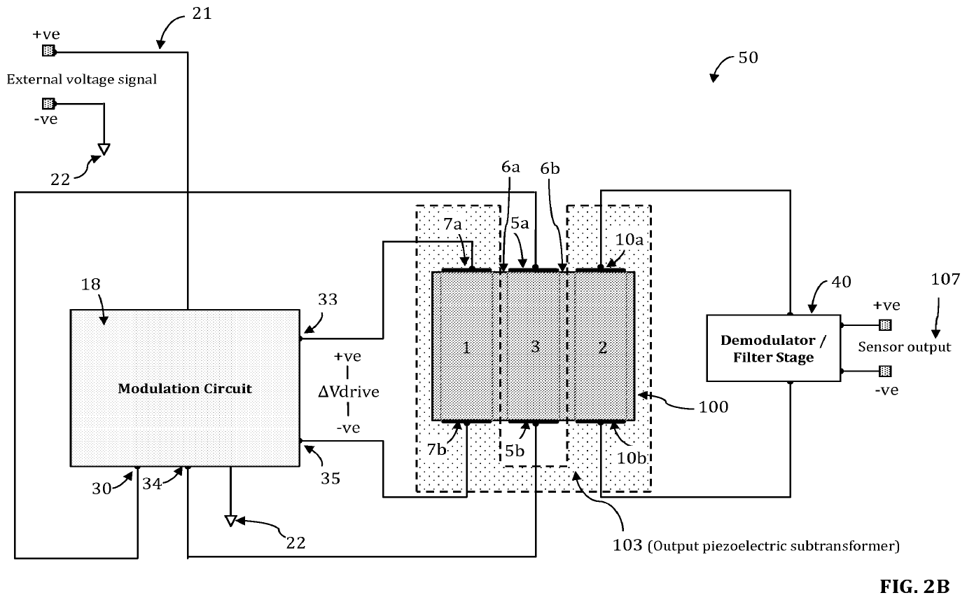

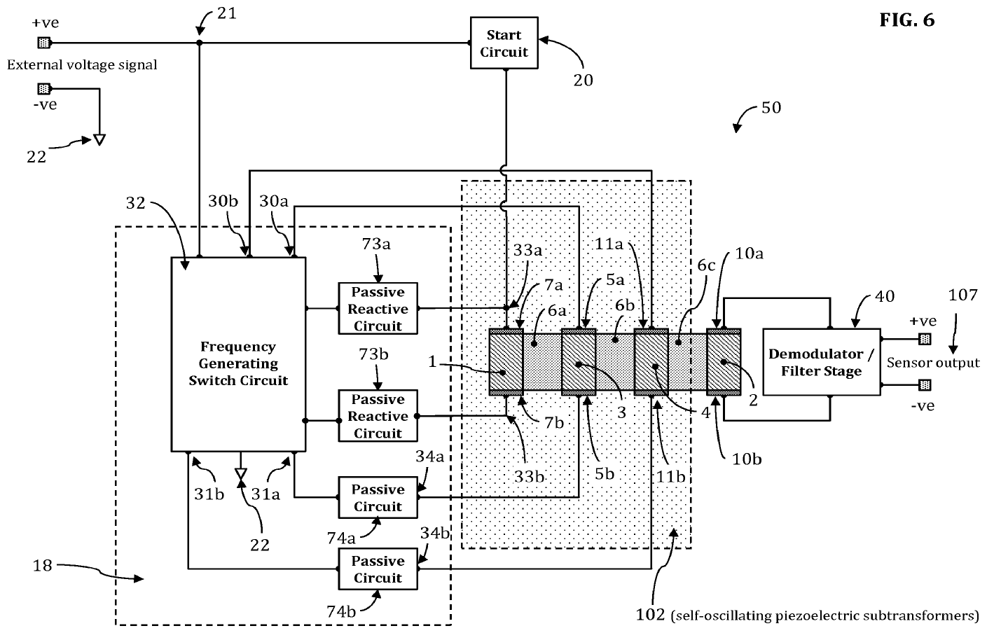

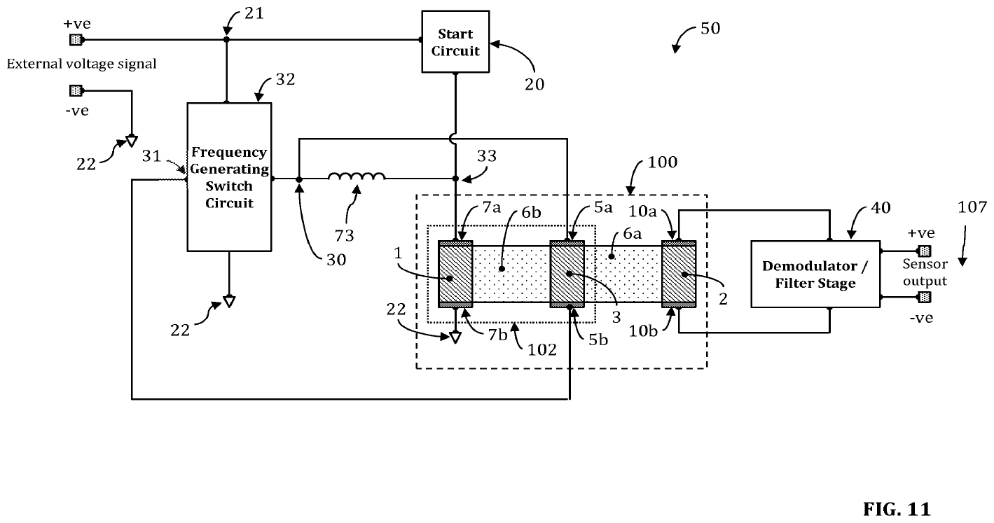

The present invention is for a voltage sensor 50 that utilizes an internal self-oscillating piezoelectric transformer circuit to modulate an external voltage signal that is to be monitored or transmitted in a galvanic isolated fashion. Referring to FIG. 2A, the piezoelectric piezoelectric transformer assembly 100 is a single mechanically integral device that incorporates two or more distinct galvanic isolated subtransformers that all share a common input side 1 that acts as a common primary side. Referring to FIG. 2A, region 102 of piezoelectric piezoelectric transformer assembly 100 forms such a subtransformer. The galvanic isolated signal transmitted is demodulated on the secondary side of one or more of the subtransformers, normally referred to as the output subtransformers. Referring to FIG. 2B, region 103 of piezoelectric piezoelectric transformer assembly 100 forms such a subtransformer. Referring to FIG. 2 and FIG. 6, one or more of these subtransformers is an integral part of the internal self-oscillating piezoelectric transformer circuit. The subtransformers of said internal self-oscillating piezoelectric transformer circuit being distinct from the output subtransformers. The inverse effect exhibited by all piezoelectric materials causes the secondary sides of all of the subtransformers of piezoelectric transformer assembly 100 to produce a sinusoidal response at a common resonant frequency that is the resonant frequency of the mechanically integral piezoelectric transformer assembly 100. This common sinusoidal frequency must always be the resonant frequency of the piezoelectric transformer assembly 100 independent of how it varies with temperature, loading, or pressure. Referring to FIG. 1, this common resonant frequency is used by the modulation circuit 18 to modulate the external voltage signal 21. According to Shannon's theory the external voltage signal 21 can be accurately reconstructed provided its bandwidth is less than 1/20^{th} of the modulation frequency. Referring to FIG. 11, the self-oscillating modulator circuit 18, as to include the self-oscillating subtransformers, can be implemented using wideband gap switches as to provide a modulation bandwidth in low GHz, therefore the invention can implement isolated voltage sensing dictated solely by the mechanical resonance of piezoelectric transformer assembly 100, which can be in the MHz range.

FIG. 1 illustrates an embodiment of the voltage sensor 50 that first modulates an external voltage signal 21 and then uses the modulated signal as the electrical excitation signal 33 of the common input side of multiple distinct and mutually isolated piezoelectric subtransformers of piezoelectric transformer assembly 100. One or more of these subtransformers has its output electrodes 10a and 10b connected to a demodulation and filter stage 40. One or more of the self-oscillation subtransformers within piezoelectric transformer assembly 100 has its output electrodes 5a and 5b connected to modulation circuit 18 as to form part of a self-oscillation circuit. In this embodiment, none of the electrodes 10a, 10b, 5a, and 5b are connected to common ground 22. The modulation circuit 18 acts to modulate the external voltage 21 using a galvanic isolated sinusoidal signal generated at the secondary taps of the self-oscillation subtransformers. As noted, this sinusoidal signal is at the mechanical frequency of piezoelectric transformer assembly 100 irrespective of which subtransformer is used as the self-oscillation subtransformers. By modulating this sinusoidal signal by the voltage signal 21 the resulting modulated signal of high side 33 and low side 35, also having the mechanical resonance of 100, are connected to the electrodes 7a and 7b respectively of the common primary side of all of the subtransformers. Typically the modulation output signal low side 35 is connected to common ground 22, but this may not be the case in certain embodiments. Because it is at mechanical resonance, the power applied to the common primary side of all of the output subtransformers has near-maximum power transfer to the secondary sides of said subtransformers. The design of the piezoelectric transformer assembly 100, including materials selection, electrode geometry and placement will determine a fixed transmission gain between the modulation signal 33 with reference to 35 and output potentials at electrode 10a in reference to those at electrode 10b. The transmitted modulation signal with gain then acts as input into a demodulation and filter stage 40. The demodulation and filter stage output voltage signal 107 is a replica of the external voltage signal 21 subject to a fixed gain that is galvanically isolated from the input voltage signal 21.

FIG. 2A together with FIG. 2B provides an embodiment of FIG. 1 wherein transformer assembly 100 includes a self-oscillation subtransformer 102 and an output subtransformer 103. In this embodiment the common input (primary) side of the subtransformers is a capacitor 1 manufactured of piezoelectric material with electrical (electroded) terminals 7a and 7b, this acts as the common primary side for all of the subtransformers of piezoelectric transformer assembly 100. The secondary side of the output subtransformer 103 is a capacitor 2 manufactured of piezoelectric material with electrical (electroded) terminals 10a and 10b. The secondary side of the self-oscillation subtransformer 102 is a capacitor 3 manufactured of piezoelectric material with electrical (electroded) terminals 5a and 5b. Although certain configurations and poling schemes can lead to requiring 7a and 5a to have the same polarity, under normal circumstances these should have opposite polarity forcing 7b and 5b to similarly have opposite polarity. One selection of polarity of 10a and 10b will maintain the polarity of the external voltage signal 21, and the other selection will invert the polarity of the external voltage signal 21. In the embodiments discussed herein, transformer assembly is comprised of ceramic materials. However, the skilled artisan will realize that the transformer assembly may be comprised of other piezoelectric materials.

Electrodes 5a and 5b are connected to inputs 30 and 34 of modulation circuit 18. Because the voltage inputs are taken from the secondary side of a piezotransformer they must necessarily be of frequency corresponding to whichever mechanical modal frequency of piezoelectric transformer assembly 100 is being primarily excited by drive signal 7a with reference to 7b. The arrangement of piezotransformer assembly 100 is that its mechanical resonance frequency is significantly greater than the bandwidth of the source voltage signal 21. This causes the high side output voltage signal 5a of the self-oscillation subtransformer 3 with reference to its low side signal 5b to be a sinusoid of frequency significantly greater than the bandwidth of the source voltage signal 21 referred to herein as the modulation carrier signal. As an edifying example, the source voltage waveform 21 with reference to 22 may have a maximum bandwidth of 400 Hz and the properties of piezoelectric transformer assembly 100 are so selected to have a first mechanical resonant frequency of 100 KHz. In some embodiments, the modulation circuit 18 is a 3-input port circuit with ground 22 common to the ground of external voltage signal 21 to be galvanic isolated tracked or transmitted. The pair of signals 5a and 5b are now of sufficient frequency as to be used as a modulation carrier signal for external voltage signal 21. The modulation circuit 18 is a 2-output port circuit and the potential difference voltage of these outputs 33 and 35 are connected to the positive and negative terminals of the common input 1 of piezoelectric transformer assembly 100. Because the frequency of the voltage waveform output voltage ΔVdrive=33-35 (referred to herein as the modulation circuit output signal) at the common input 1 of modulation circuit 18 is determined by the modulation carrier frequency ΔVmodulate=5a-5b, which, by the laws of physics, has to be precisely at the mechanical frequency of piezoelectric transformer assembly 100, the drive frequency of capacitor 1 is always identical to the mechanical frequency of piezoelectric transformer assembly 100 independent of time, temperature, pressure, or loading conditions. Therefore, the modulation circuit acts to modulate the external voltage 21 with a carrier signal that is suitably high that is completely determined by the mechanical behavior of piezoelectric transformer assembly 100 and is at the mechanical resonance of piezoelectric transformer assembly 100. By the laws of physics, this sinusoidal modulated signal (modulation circuit output signal) appearing across the electrodes 7a and 7b of the output piezotransformer is recreated across the electrodes 10a and 10b at the secondary side of the output subtransformer 2 subject to the output transformer gain. A standard demodulator 40, typically with added filter, will recreate the external voltage signal 21, subject to the same output subtransformer gain.

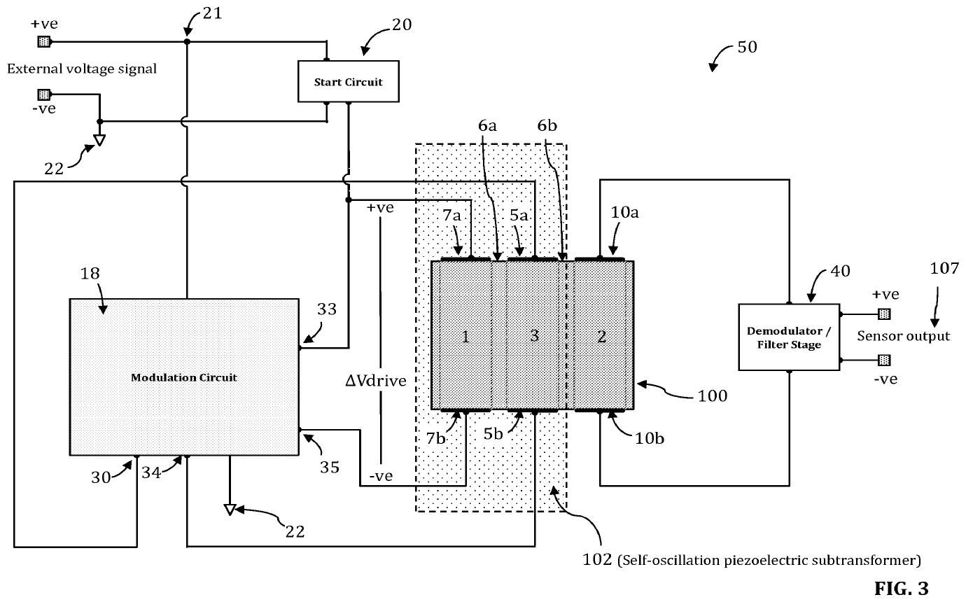

In certain situations, typically when tracking very low strength voltage signals, the signal source 21 may not be sufficient to initiate the modulation process and cannot be relied upon to start-up the voltage sensor 50. FIG. 3 provides a method that ensures that the isolated voltage sensor is operating. A start circuit 20 is added that takes its power from the voltage source signal 21 to be monitored. The start circuit output connects to the positive electrode termination 7a of common input 1, as to induce an initial non-zero potential ΔVdrive across common input 1. For multilayer configurations of piezoelectric transformer 100, where 7a includes a set of electrodes with common reference 7b the output of the start circuit 20 need only be connected to one such electrode. The voltage produced by the start circuit can alternatively be connected to electrode 5a or electrode 10a, as to initiate the operation of isolated voltage sensor device 50. The start circuit 20 provides sufficient energy into the piezoelectric transformer assembly 100 as to cause a sinusoidal voltage waveform ΔVmodulate=5a-5b be sufficient as to cause a potential ΔVdrive across common input 1. A specific mechanical mode i.e. resonant frequency for operation of device 50 may be selected by simply ensuring that the drive signal output waveform of 20 has a frequency that is reasonably close to that selected resonance as to not couple with a nearby resonance mode. For most applications of device 50 the selected frequency will be the fundamental frequency; however a higher mode may be selected for the purpose of developing a higher frequency sinusoidal modulation input into modulation circuit 18 for applications such as isolated transmission of a digital signal source 21.

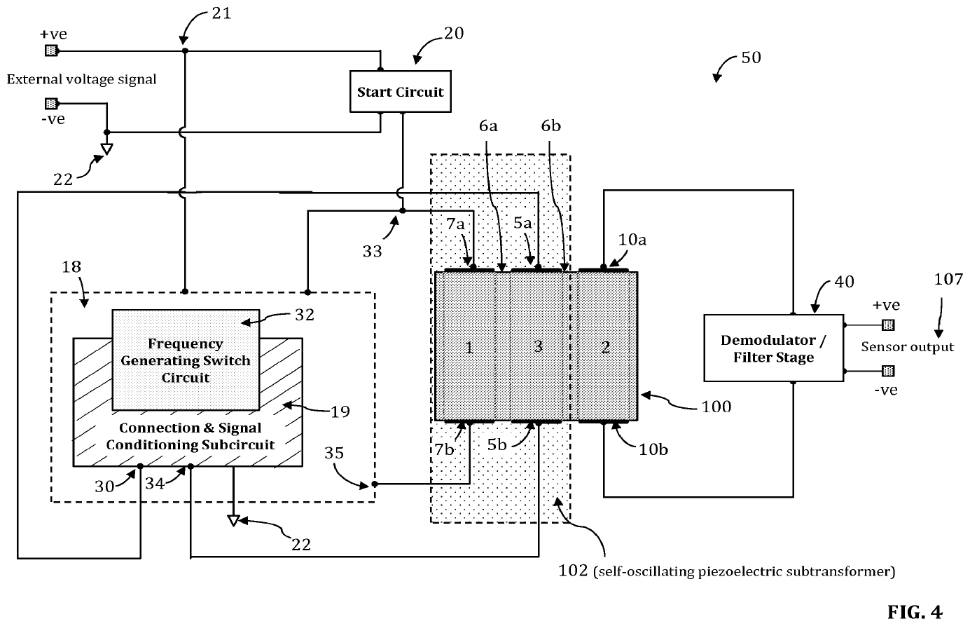

In accordance with an embodiment of the present invention described in FIG. 4, the modulation circuit 18 may be comprised of two interconnected subcircuits: a frequency generating switch subcircuit 32 and a connection and signal conditioning subcircuit 19. The external voltage signal 21 to be monitored or tracked in an isolated fashion is connected to frequency generating subcircuit 32 and shares common ground 22. Signal conditioning subcircuit 19 conditions the sinusoidal signal ΔVmodulate that enters at ports 30 and 34, the resulting conditioned signal being at the same frequency as ΔVmodulate. The resulting conditioned signal is then injected as a drive carrier signal into the frequency generating switch circuit 32 with reference to ground 22. The output of the frequency generating switch circuit 32 is further conditioned by another part of connection and signal conditioning subcircuit 19 before being connected to the terminals 7a and 7b of the common input 1.

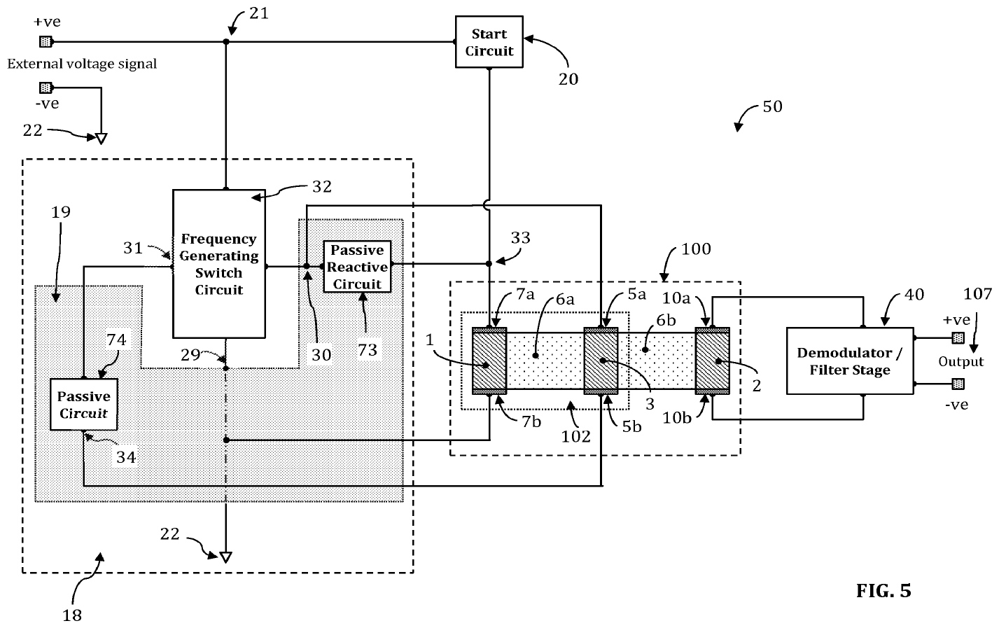

FIG. 5 is an embodiment of device of FIG. 4 wherein the connection & signal conditioning subcircuit 19 has a first part consisting of a passive circuit 74 with input port 34 connected to 5b, and a second part 73 with input port 30 connected to both 7a and the non-ground output of the frequency generating switch subcircuit 32. By this arrangement the passive circuit 74 provides a high frequency injection signal into the frequency generating switch subcircuit 32 at its input port 31 at exactly the mechanical resonance frequency of piezoelectric transformer assembly 100. The start circuit 20 is configured so that subsequent to startup of device 50 the voltage contribution of start circuit 20, as seen at node 33, becomes redundant and can therefore be removed. Examples of circuits that are suitable to function as a start circuit 20 and that will automatically shut down once the self-sustaining internal source follower becomes active are further described below.

FIG. 6 is an embodiment of the device of FIG. 4 wherein the connection and signal conditioning subcircuit 19 has a first part consisting of passive circuits 74a and 74b disposed between terminal 5b and terminal 11b, respectively, and input ports 31b and 31a, respectively, of the frequency generating switch subcircuit 32. By this arrangement the passive circuit 19 provides a high frequency injection signal into the frequency generating switch subcircuit 32 at input ports 31a and 31b both having a sinusoidal frequency at the mechanical resonance frequency of piezoelectric transformer assembly 100. The connection and signal conditioning subcircuit 19 has a second part consisting of passive circuits 73a and 73b disposed between input port 30a and 30b and the high side 7a and the low side 7b of the common primary side 1. As with previous circuits and figures, this is presented in its simplest form for expository purpose, as it is commensurate with the simplest embodiment of the frequency generating switch circuit 32 that consists of a switching full-bridge circuit. The start circuit 20 is configured so that subsequent to start-up of device 50 the voltage contribution of start circuit 20, as seen at node 33a, becomes redundant and can therefore be removed. Examples of circuits that are suitable to function as a start circuit 20 and that will automatically shut down once the self-sustaining internal source follower becomes active are further described below.

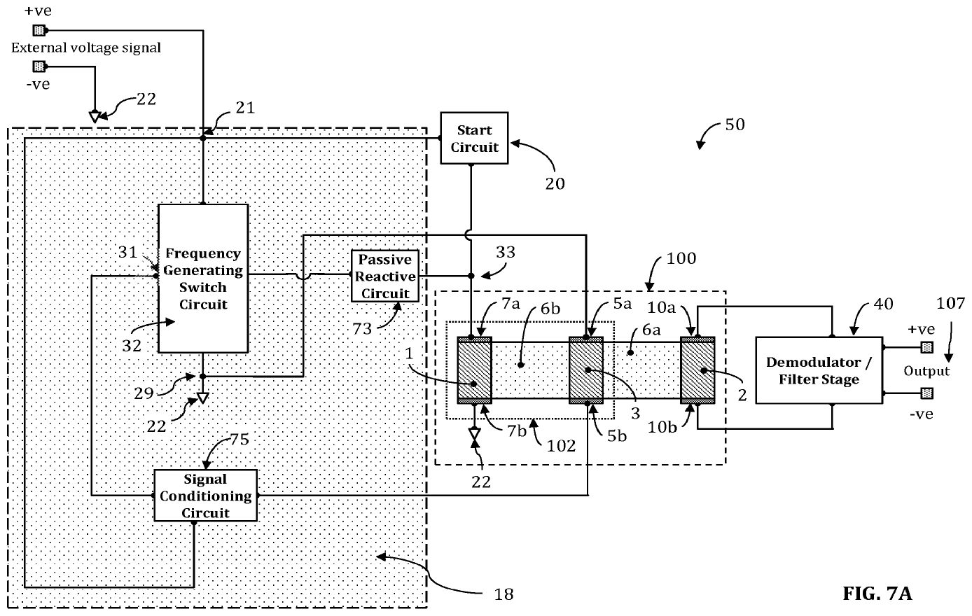

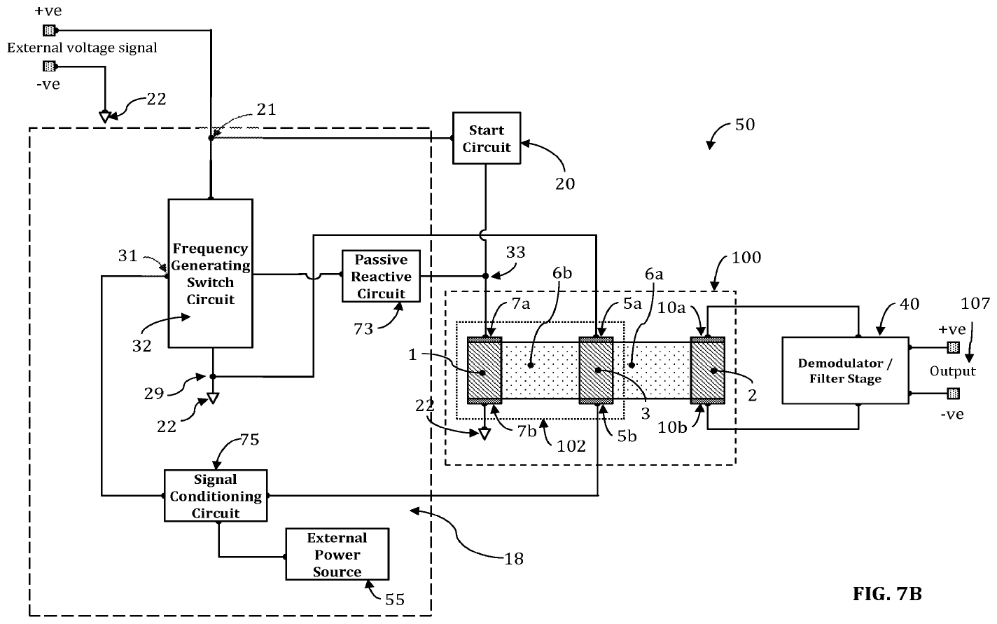

FIG. 7A provides an embodiment of the invention described in FIG. 5 with the following distinctions: (i) a signal conditioning circuit 75, replacing the passive circuit 74, is interposed between the input port 31 of frequency generating switch circuit 32 and the low-side output 5b of the self-oscillating subtransformer 3; (ii) the high-side output of tertiary 5b of self-oscillating subtransformer 3 is connected to common ground 22. In this configuration the electron flow loop 22, 5a, 5b, 31, 33, 7a, 7b, 22 forms a closed self-resonant subcircuit that resonates at a mechanical resonance frequency of piezoelectric transformer assembly 100 where this resonance selection is determined by the start circuit 20 or will default to the fundamental first resonance of piezoelectric transformer assembly 100 in the absence of such a start circuit 20. The signal conditioning circuit 75 derives its power from the voltage source signal 22.

FIG. 7B provides an embodiment of the invention described by FIG. 5 that is identical to that described in FIG. 7A with the exception being that an external power source 55 is now used to supply power to the signal conditioning circuit 75.

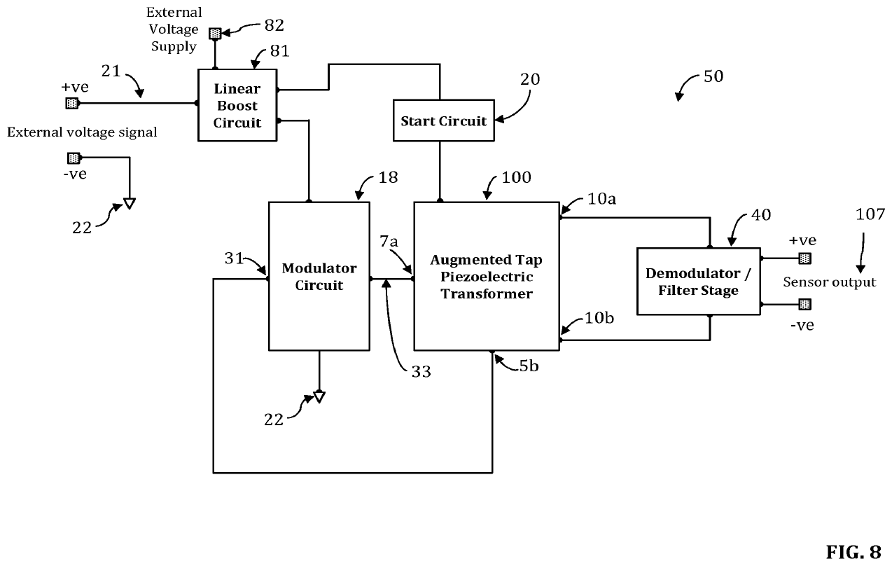

FIG. 8 provides a modification of FIG. 1 designed for situations where the signal strength of the source voltage waveform 21 is too low to initiate or maintain the operation of device 50. This embodiment is identical to that described by FIG. 1 with the distinction that a linear boost circuit 81 is interposed between the source voltage signal 21 and the modulation circuit 18. The linear boost circuit derives its power from an external voltage source 82. The start circuit 20 may also be boosted by the linear boost circuit 81.

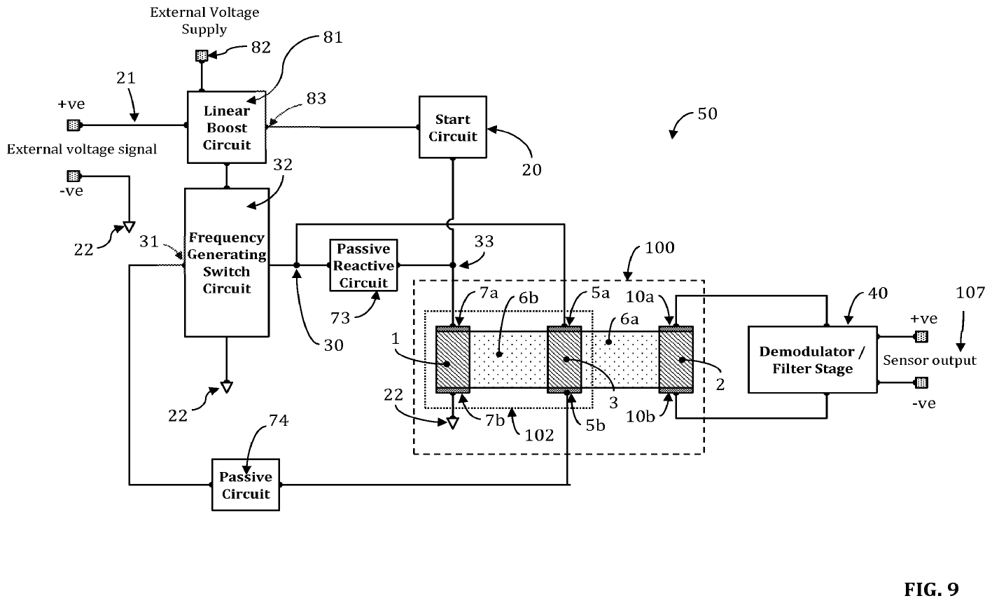

FIG. 9 provides for an embodiment of the invention that is applicable to the monitoring of small or very small signal voltage waveforms where the source voltage 21 may be insufficient to enable the start circuit 20 to correctly function as to enable electron flow in the switch circuit 31. The start circuit 20 is boosted by an additional amplification pre-stage such as linear boost circuit 81 which is powered by an external voltage source 82. The output at node 83 of linear boost circuit 81 would be selected as to provide sufficient energy as to enable the start circuit 20 to electrically excite the common subtransformers input 1 as to produce sufficient power at the output 5b of the self-oscillation subtransformer 3. The linear boost circuit 81 may also continue to boost the external voltage signal input 21 as to assist in continuing to supply sufficient current as to maintain self-drive operation as described in FIG. 5.

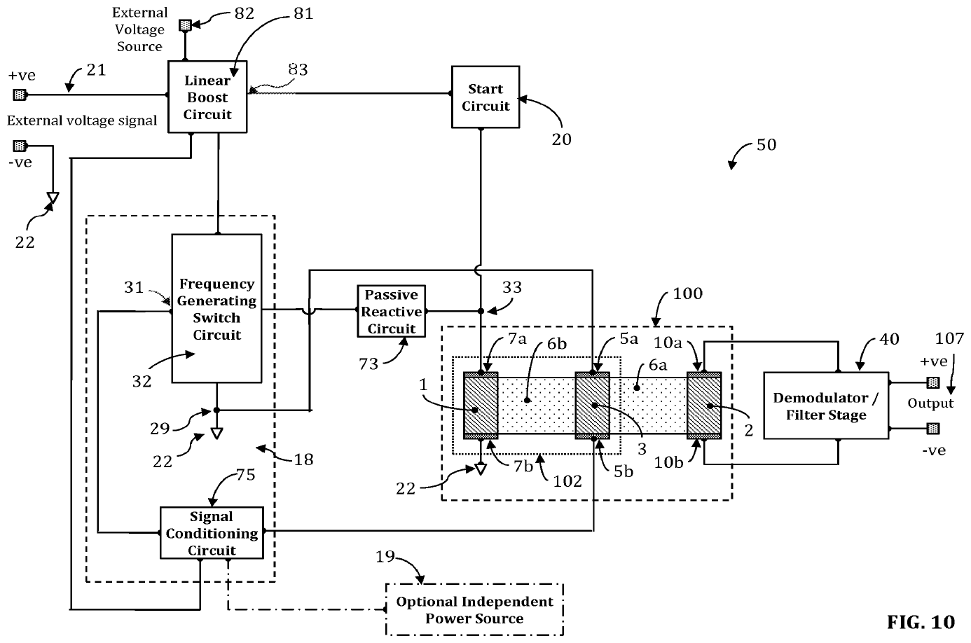

FIG. 10 provides for an embodiment of the invention that is applicable to monitoring small, or very small, signal voltage waveforms where the external voltage signal 21 may be insufficient to enable the start circuit 20 to cause the self-oscillation subcircuitry of 50 to initiate. The start circuit 20 is now boosted by an additional amplification pre-stage 81 supplied by an external voltage source 82. The output port 83 of 81 now provides sufficiently strong power characteristics as to enable the self-oscillation subcircuitry of 50 to initiate. The linear boost circuit 81 may be employed also continue to boost the sensor input 21 as to assist in continuing to supply sufficient current as to maintain proper operation of the self-oscillation subcircuitry. The signal conditioning circuit 75 may either derive its power from the amplification pre-stage 81 or may derive its power from an independent power source 19, such as a battery or super capacitor.

FIG. 11 provides an embodiment of the galvanic isolated voltage sensor 50 as described in FIG. 5. In this embodiment the passive circuit 74 consists of a short circuit and the passive reactive circuit 73 consists of an inductor. This embodiment is conducive to half-bridge implementations of the frequency generating switch circuit 32. A similar second embodiment of the galvanic isolated voltage sensor 50 can be obtained by making the same second subcircuit selections for the passive circuit devices 74a and 74b and passive reactive circuit 73a and 73b as described in FIG. 6. Such an embodiment will be conducive to full-bridge implementations of the frequency generating switch circuit 32.

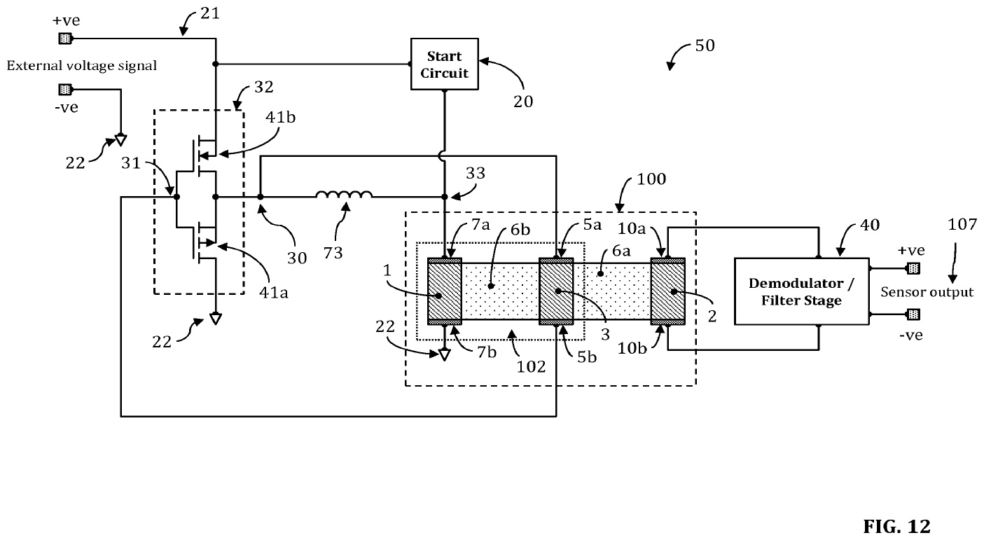

FIG. 12 provides a low part count embodiment of the galvanic isolated voltage sensor 50 as described in FIG. 1. In this embodiment the passive circuit 74 consists of a short circuit and the passive reactive circuit 73 consists of an inductor. In this embodiment the frequency generating switch circuit 32 is a half-bridge transistor circuit consisting of an n-channel MOSFET device 41b and a p-channel MOSFET device 41b. Its input power is the external voltage signal input 21, its gate drive is provided by connecting the low-side output 5b of the secondary side 3 of the oscillating subtransformer 102 to the gate at port 31, and its output is connected to inductor 73 that is interposed between the high-side output 5a of the secondary side of the of the oscillating subtransformer 102 and the high-side 7a of the common primary side 1. Other selections of transistor devices will provide alternate embodiments.

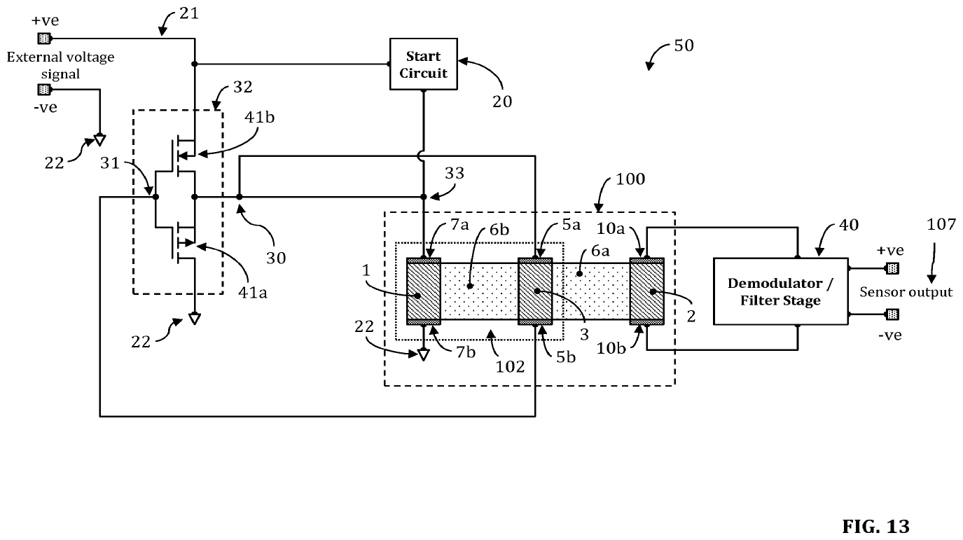

FIG. 13 provides a low part count embodiment of the galvanic isolated voltage sensor 50 identical to FIG. 12 except that the passive reactive circuit 73 now consists of a short circuit the drive carrier wave excitation of the common input side of the subtransformers is now the (voltage source signal) modulated square wave pulse train waveform at node 56 produced by the power half-bridge. Due to potential crack initiation of the ceramic due to driving the input (primary) side of the subtransformers with a square wave pulse train this embodiment should only be employed for short duration or low duty cycle applications.

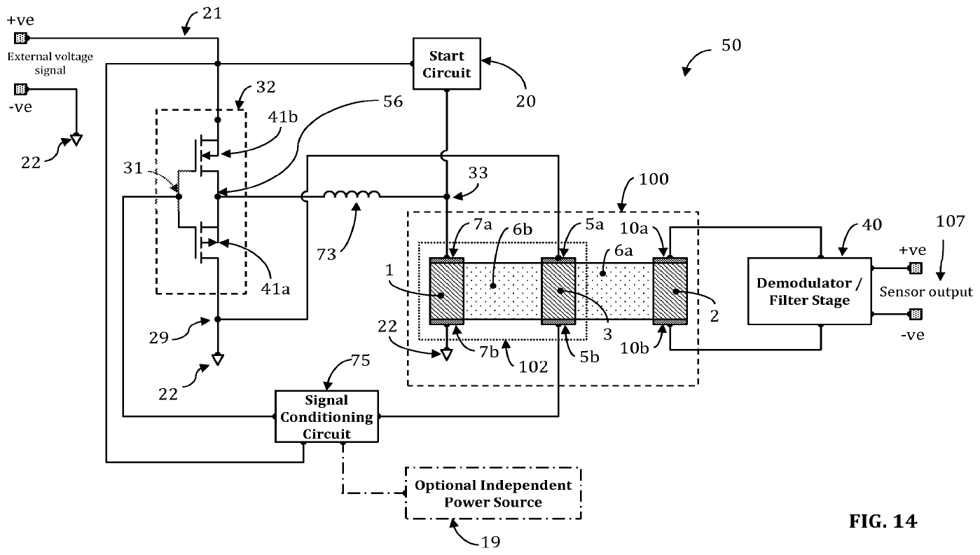

FIG. 14 provides a low part count embodiment of the galvanic isolated voltage sensor 50 that functions similar to that described by FIG. 11 and FIG. 12 with the following distinctions: (i) An active signal conditioning circuit 75 that replaces the short circuit 74 is interposed between the low-side electrical terminal 5b of the self-oscillating subtransformer and the gate signal port 31 of a transistor half-bridge 32; (ii) The high-side terminal 5a of the self-oscillating subtransformer is connected to the common ground 22. The active signal conditioning circuit 75 may derive its power from the voltage signal source 21, linear boost circuit 81 (not shown), or an independent power source 19, such as a battery or super capacitor. A second low part count full-bridge embodiment of the galvanic isolated voltage sensor 50 can be obtained by making the similar connections to a signal conditioning circuit 75 that now replaces 74a and 74b of FIG. 6, and a full-bridge implementation of the frequency generating switch circuit 32 as described in FIG. 6.

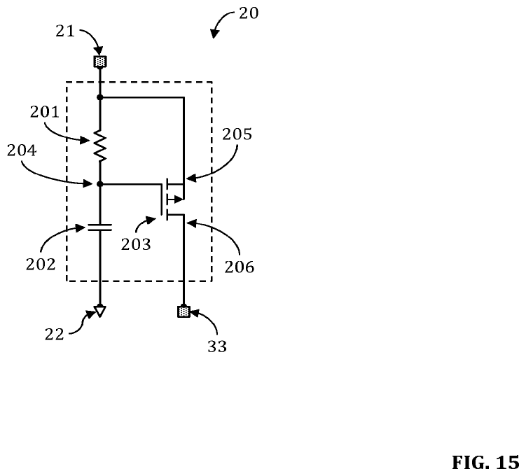

FIG. 15 provides an example of start circuit 20 of FIG. 3 that is of a low part count. For this embodiment a MOSFET 203 is selected as either a depletion n-channel or depletion p-channel. MOSFET 203 has source terminal 205 is connected to the external voltage signal at node 21 and its drain terminal 206 is connected to node 33. The gate terminal 204 of 203 is terminated at the connection between the two components of a series RC circuit formed by resistor 201 and capacitor 202 that is itself disposed between the high-side voltage of the external signal 21 and common ground 22. Depletion-mode MOSFET devices are doped so that a channel exists even with zero voltage VGs between gate terminal 204 and source terminal 206. To control the channel, a negative voltage is applied to the gate for an n-channel device, depleting the channel, which pinches off the electron flow through the device. Similarly a positive voltage is applied to the gate for a p-channel device. Upon start up there is no charge flow between voltage signal 21 and ground 22 and therefore the MOSFET device is closed enabling charge to flow from Vcc directly into node 33 connected to the first terminal 7a of section 1 of the transformer subcircuit 102. This causes a pulse voltage waveform at the high-side terminal 7a of the secondary of the self-oscillating subtransformer referenced to common ground 22. Because the transformer subcircuit 102 is comprised of piezoelectric materials the waveform 33 must cause a non-zero sinusoidal voltage waveform at the output side of the transformer 102. The power of this waveform being entirely dependent on the supply, where the supply is signal 21 i.e. Vcc=Vsignal (21) or, if insufficient, provided by an external power source 82. As determined by the RC time constant of the start circuit, Vg increases the voltage at the gate of the device. Correctly selected RC components will provide sufficient positive voltage as cause the depletion MOSFET device to become open as to prevent any further current flow through node 33, apart from very small subthreshold leakage, between Vcc and node 33.

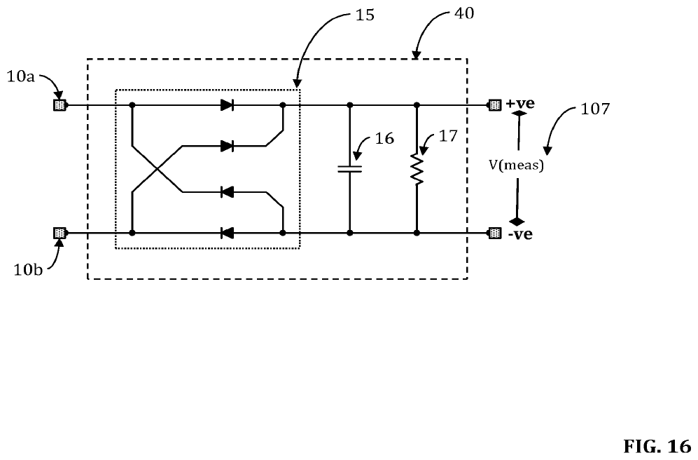

FIG. 16 provides an example of a suitable demodulation and filter circuit 40 of the invention FIG. 1. The embodiment provides a passive component solution to implementing of the demodulation/filter of the invention with a minimal number of components. The demodulation/filter embodiment employs such a full wave diode rectifier and RC filter. In this embodiment first terminal 10a and second terminal 10b are connected at nodal inputs to a two-wire input of a full-wave diode bridge 15 whose two wire outputs are connected across a parallel RC circuit formed by capacitor 16 and resistor 17. The negative terminal 10b is floating, and not connected to common ground 22, as to ensure high galvanic isolation of the voltage sensor. The effective bandwidth of the voltage sensor is determined by selection of components 16 and 17. The resulting isolated copy of the original external voltage signal 21 is given by V (meas) 107. The accuracy of 107 in duplicating 21, subject to the gain of the transformer, requires that the capacitance should be selected as to not damp the measurement waveform signal; moreover, the resulting RC constant should ensure minimal attenuation below its cutoff frequency (=1/RC). An obvious modification requiring the same minimal number of components would employ an RC divider network connected to the output of the full wave rectifier 15. Other demodulation/filter subcircuit embodiments of prior art can be employed for demodulation/filter of the output ac signal of piezoelectric transformer assembly 100; for example, incorporating an active low pass filter design as to introduce additional signal gain and stopband characteristics.

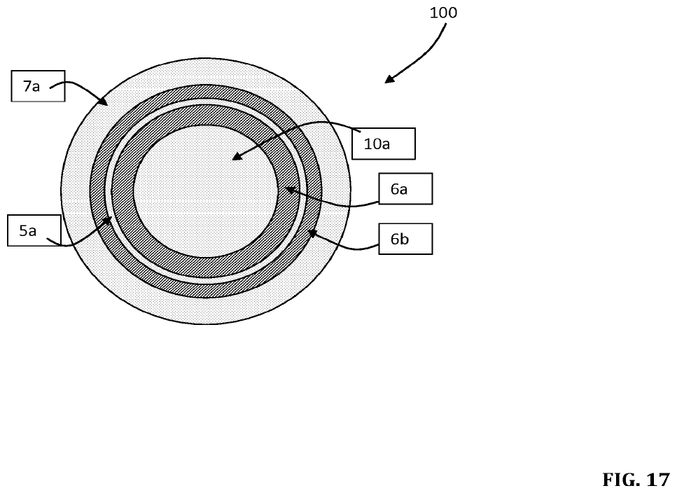

FIG. 17 provides a top view flat planar embodiment of piezoelectric transformer assembly 100 that consists of concentric rings that alternate between electroded regions and non-electroded regions. The piezoelectric transformer assembly 100 is symmetrically electroded so that the underside is identical to its topside (shown). Its planar shape shown as a disc can also have annular, square, oval or other planar geometry, each featuring a similar series of nested regions that are alternately electroded and non electroded.

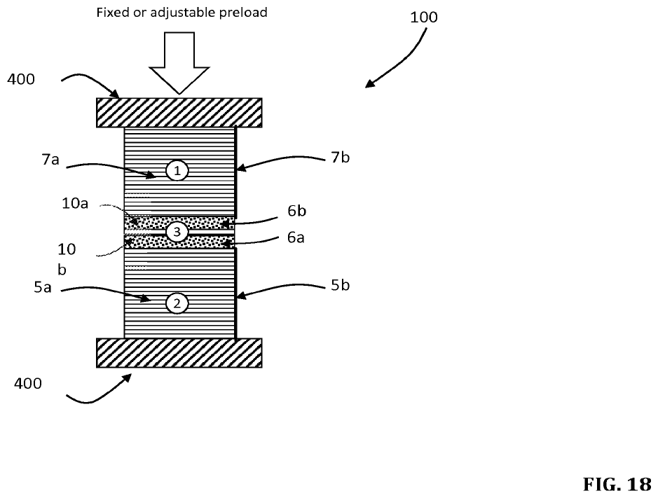

FIG. 18 provides an embodiment of piezoelectric transformer assembly 100 that consists of two piezoelectric devices 1 and 2, which are either monolithic or multilayer, separated by a third piezoelectric 3 by non-conductive layers 6a and 6b. The piezoelectric devices and non-conductive layers sharing near identical planar footprint are captured in a housing 400 that induces a fixed or a variable preload on the captured piezoelectrics 1, 2 and 3.

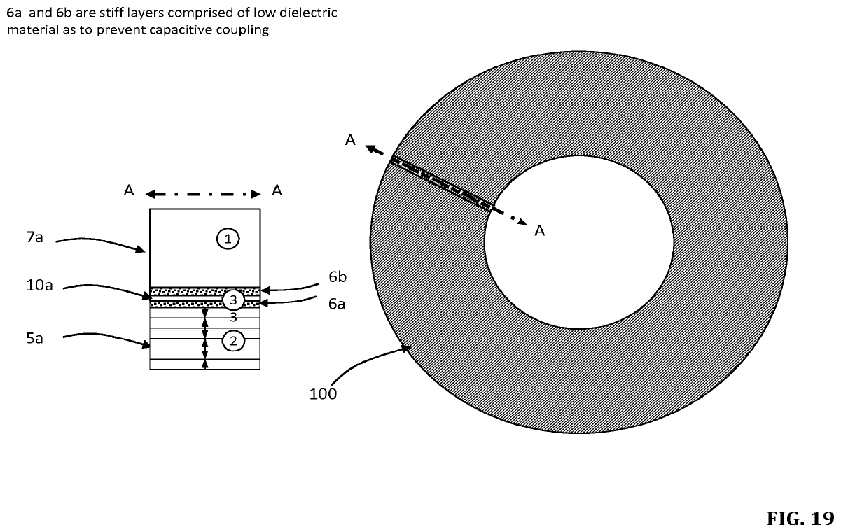

FIG. 19 provides an embodiment of piezoelectric transformer assembly 100 that consists of a thick circular washer whose cross section is shown in cut A-A. The common input 1 consists of a single monolithic piezoelectric, the output 2 consists of a multilayer piezoelectric, and the self-oscillation device 3 consists of a single layer piezoelectric 3 separated from 1 and 2 by non-conductive rings 6a and 6b. The piezoelectric devices and non-conductive layers sharing near identical planar footprint.

The device and its embodiments shown in FIG. 1 to FIG. 19 may further incorporate one or more additional galvanic isolated self-oscillation electroded subtransformers, as exampled in FIG. 6, as to provide a separate reference signal to another device or circuit. The device and its embodiments shown in FIG. 1 to FIG. 19 may further incorporate one or more additional galvanic isolated output subtransformers as to provide multiple reference signals or control signals to multiple devices.

The device and its embodiments shown in FIG. 1 to FIG. 19 may have a frequency generating switch circuit comprised of low power transistor (emitter-gain-collector topology) devices for small signal (low power) voltage measurement and/or tracking whereas MOSFET (source-gate-drain topology) devices might normally be employed for high power voltage measurement and/or tracking. Alternate frequency generator circuits 32 might be used, such as a super source follower circuit to enhance the low input voltage linearity, or other configured circuit architecture that provides increased stability. Modifications of the subcircuits might be used when employing low power transistor devices to monitor and/or track a small signal voltage. With obvious modifications of the self-drive subcircuit of FIG. 2A/2B and its embodiments, monitoring of DC voltage fluctuation, as opposed to AC voltage measurement, can be accomplished using just a single transistor switch device.

The accompanying drawings illustrate embodiment and prototype examples of the invention. Based on this disclosure, one of ordinary skill in the art will appreciate that the use of “same”, “identical” and other similar words are inclusive of differences that would arise during manufacturing to reflect typical tolerances for goods of this type.

As used above “substantially,” “generally,” and other words of degree are relative modifiers intended to indicate permissible variation from the characteristic so modified. It is not intended to be limited to the absolute value or characteristic which it modifies but rather possessing more of the physical or functional characteristic than its opposite, and preferably, approaching or approximating such a physical or functional characteristic. “Substantially” also is used to reflect the existence of manufacturing tolerances that exist for manufacturing components.

It should be noted that the present invention may, however, be embodied in many different forms and should not be construed as limited to the embodiments and prototype examples set forth herein; rather, the embodiments set forth herein are provided so that the disclosure will be thorough and complete, and will fully convey the scope of the invention to those skilled in the art. The accompanying drawings illustrate embodiment and prototype examples of the invention. Based on this disclosure, one of ordinary skill in the art will appreciate that the use of “same”, “identical” and other similar words are inclusive of differences that would arise during manufacturing to reflect typical tolerances for goods of this type.

### REFERENCES

[1] Parag V. Acharya and Fred H. Boettner, US Patent US 20130027238 A1, (2013)
[2] Paul Horowitz and Winfield Hill, “The Art of Electronics 2nd Ed.,” (1989)
[3] Xueuing Qui, U.S. Pat. No. 5,361,037 (1994)
[4] Josef Nossek, U.S. Pat. No. 4,354,169 (1982)
[5] Xueuing Qui, U.S. Pat. No. 5,361,037 (1993)
[6] Pentti Mannonen, U.S. Pat. No. 6,549,056 (2003)
[7] M Pacheco, F. Mendoza Santoyo, A Méndez and L A Zenteno, “Piezoelectric-modulated optical fibre Bragg grating high-voltage sensor,” Measurement Science and Technology Volume 10, Number 9 (1999)
[8] K Kawamura et al, ‘Development of a high voltage sensor using a piezoelectric transducer and a strain gage,’ IEEE Trans. Instrum. Meas. 37 564-8
[9] M Pacheco et al, ‘Piezoelectric-modulated optical fibre Bragg grating high-voltage sensor,’ Meas. Science and Technology 09/1999; 10:777-782
[10] M Mozafari et al, ‘Design and fabrication of piezo-optical Fabry-Perot voltage sensor,’ Avionics, Fiber-Optics and Photonics Technology Conference, 2008
[11] A Carazo, “Novel Piezoelectric Transducers for High Voltage Measurements,” Ph.D. Thesis, Universitat Politàcnica De Catalunya, 2000
[12] Svetlana Bronstein and Sam Ben-Yaakov, “Design Considerations for Achieving ZVS in a Half Bridge Inverter that Drives a Piezoelectric Transformer with No Series Inductor,” DOI:10.1109/PSEC.2002.1022516 In proceeding of: Power Electronics Specialists Conference, 2002. pesc 02. 2002 IEEE 33rd Annual, Volume 2, (2012)

We claim:

1. A voltage sensor comprising:
a mechanically integral piezoelectric transformer assembly having at least first and second distinct galvanically isolated outputs and at least one input, said mechanically integral piezoelectric transformer assembly generating a modulation carrier signal having a frequency equal to a mechanical resonance frequency of said mechanically integral piezoelectric transformer assembly;
a modulation circuit having a first input coupled to the first galvanically isolated output of said mechanically integral piezoelectric transformer assembly causing a modulation carrier signal to be generated by said modulation circuit, said modulation circuit receiving a source voltage signal and modulating the source voltage signal with the modulation carrier signal as to generate a modulation circuit output signal, said modulation circuit being connected to and transmitting the modulation circuit output signal to at least one input of said mechanically integral piezoelectric transformer assembly, thereby forming an internal self-oscillating circuit including said modulation circuit and said piezoelectric transformer assembly;
one or more demodulators coupled to the one or more outputs of said mechanically integral piezoelectric transformer assembly, where said mechanically integral piezoelectric transformer assembly outputs a piezoelectric transformer assembly signal that is proportional to the carrier modulated voltage source signal.

2. The voltage sensor of claim 1 wherein said mechanically integral piezoelectric transformer assembly includes at least first and second galvanically isolated subtransformers sharing a common primary side, the first subtransformer having part of its output coupled to said modulation circuit as to supply the carrier signal form the internal self-oscillation circuit and the second subtransformer being coupled to one of said demodulators.

3. The voltage sensor of claim 2 wherein the common primary side of said mechanically integral piezoelectric transformer assembly includes a capacitive section provided with first and second electrodes coupled to an output of said modulation circuit, the secondary side of the first subtransformer includes a capacitive section having first and second electrodes coupled to an input of said demodulator, and the secondary side of the second subtransformer includes a capacitive section having first and second electrodes coupled to an input of said modulation circuit.

4. A voltage sensor comprising:
a mechanically integral piezoelectric transformer assembly having at least first and second distinct galvanically isolated outputs and at least one input, said mechanically integral piezoelectric transformer assembly generating a modulation carrier signal having a frequency equal to a mechanical resonance frequency of said mechanically integral piezoelectric transformer assembly;
a start circuit operatively coupled to said mechanically integral piezoelectric transformer assembly to initiate transformer operation;
a modulation circuit having a first input coupled to the first galvanically isolated output of said mechanically integral piezoelectric transformer assembly and receiving the modulation carrier signal, said modulation circuit receiving a source voltage signal and modulating the source voltage signal with the modulation carrier signal to generate a modulation circuit output signal, said modulation circuit being connected to and transmitting the modulation circuit output signal to at least one input of said mechanically integral piezoelectric transformer assembly, thereby forming an internal self-oscillating circuit including the combination of said modulation circuit and said piezoelectric transformer assembly;
one or more demodulators coupled to the one or more outputs of said mechanically integral piezoelectric transformer assembly, where said mechanically integral piezoelectric transformer assembly outputs a piezoelectric transformer assembly signal that is proportional to the modulated voltage source signal.

5. The voltage sensor of claim 4 wherein said mechanically integral piezoelectric transformer assembly includes at least first and second galvanically isolated subtransformers having a common primary side, said start circuit being connected to said primary side and the first subtransformer being coupled to said modulation circuit and the second subtransformer being coupled to one of said demodulators.

6. The voltage sensor of claim 5 wherein the common primary side includes a capacitive section provided with first and second electrodes coupled to an output of said modulation circuit, a secondary side of the second subtransformer includes a capacitive section having first and second electrodes coupled to an input of said demodulator, and a secondary side of the first subtransformer includes a capacitive section having first and second electrodes coupled to an input of said modulation circuit.

7. The voltage sensor of claim 6 wherein said modulation circuit includes a frequency generating switch subcircuit that receives the source voltage signal and a connection and signal conditioning subcircuit that receives the modulation carrier signal.

8. The voltage sensor of claim 6 wherein said modulation circuit includes:
a frequency generating switch subcircuit that receives the source voltage signal;
a passive circuit having an input coupled to the secondary side of the first subtransformer and an output connected to one or more inputs of the frequency generating switch circuit; and
a passive reactive circuit having an input connected to an output of the frequency generating switch circuit and to the common primary side of said piezoelectric transformer assembly.

9. The voltage sensor of claim 8 wherein the passive circuit is a short circuit and the passive reactive circuit is an inductor.

10. The voltage sensor of claim 9 wherein the frequency generating switch circuit includes a half bridge circuit.

11. The voltage sensor of claim 8 wherein the passive reactive circuit is a short circuit, the passive reactive circuit is a short circuit and the frequency generating switch subcircuit includes a half bridge circuit.

12. The voltage sensor of claim 4 wherein said modulation circuit includes:
a frequency generating switch subcircuit that receives the source voltage signal;
a signal conditioning circuit having an input coupled to a first part of the first galvanically isolated output with as second part of the first galvanically isolated output connected to ground and an output connected to an input of the frequency generating switch circuit; and
a passive reactive circuit having an input connected to an output of the frequency generating switch circuit and having an output coupled to the common primary side.

13. The voltage sensor of claim 12 wherein the signal conditioning circuit is powered by one of the source voltage signal and an external power source.

14. The voltage sensor of claim 12 wherein the passive reactive circuit is an inductor and the frequency generating switch subcircuit includes a half bridge circuit.

15. A voltage sensor comprising:
a mechanically integral piezoelectric transformer assembly having at least first and second distinct galvanically isolated outputs and at least one input, said mechanically integral piezoelectric transformer assembly generating a modulation carrier signal having a frequency equal to a mechanical resonance frequency of said mechanically integral piezoelectric transformer assembly;
a linear boost circuit that receives a source voltage signal and amplifies source voltage signal;
a start circuit operatively coupled to said mechanically integral piezoelectric transformer assembly to initiate transformer operation;
a modulation circuit having a first input coupled to the first galvanically isolated output of said mechanically integral piezoelectric transformer assembly and receiving the modulation carrier signal, said modulation circuit generating an amplified source voltage signal and modulating the amplified source voltage signal with the modulation carrier signal to generate a modulation circuit output signal, said modulation circuit being connected to and transmitting the modulation circuit output signal to at least one input of said mechanically integral piezoelectric transformer assembly, thereby forming an internal self-oscillating circuit including said modulation circuit and said piezoelectric transformer assembly;
one or more demodulators coupled to the one or more outputs of said mechanically integral piezoelectric transformer assembly, where said mechanically integral piezoelectric transformer assembly outputs a piezoelectric transformer assembly signal that is proportional to the modulated voltage source signal.

16. The voltage sensor of claim 15 wherein said mechanically integral piezoelectric transformer assembly includes at least first and second galvanically isolated subtransformers having a common primary side, said start circuit being connected to said primary side and the first subtransformer being coupled to said modulation circuit and the second subtransformer being coupled to one of said demodulators.

17. The voltage sensor of claim 16 wherein the common primary side includes a capacitive section provided with first and second electrodes, the secondary side of the second subtransformer includes a capacitive section having first and second electrodes coupled to an input of said demodulator, and a secondary side of the first subtransformer includes a capacitive section having first and second electrodes connected to said modulation circuit.

18. The voltage sensor of claim 17 wherein said modulation circuit includes:
a frequency generating switch subcircuit that receives the amplified source voltage signal;
a passive circuit having an input coupled to the one of the first and second electrodes of the secondary side of the first subtransformer and an output connected to an input of the frequency generating switch circuit; and
a passive reactive circuit having an input connected to an output of the frequency generating switch circuit and one of the first and second electrodes of the secondary side of the first transformer and having an output connected to one of the first and second electrodes of the common primary side.

19. The voltage sensor of claim 16 wherein said modulation circuit includes:
a frequency generating switch subcircuit that receives the amplified source voltage signal;
a signal conditioning circuit having an input coupled to one of the first and second electrodes of the secondary side of the first subtransformer and an output connected to an input of the frequency generating switch circuit; and
a passive reactive circuit having an input connected to an output of the frequency generating switch circuit and an output connected to an input terminal of the common primary side where the other input of the common primary side is connected to ground.

20. The voltage sensor of claim 19 wherein the signal conditioning circuit is powered by one of the source voltage signal and an external power source.

21. The voltage sensor of claim 4 wherein said start circuit includes means for automatically shutting off once transformer operation is initiated.

22. The voltage sensor of claim 4 wherein said start circuit automatically turns on as to initiate the self-oscillating circuit and that automatically shuts off once transformer operation is initiated.
